(19) United States
(12) Patent Application Publication
(10) Pub. No.: US 2017/0099746 A1
(43) Pub. Date: Apr. 6, 2017

(54) LAYERED AIRFLOW COOLING FOR ELECTRONIC COMPONENTS

(71) Applicant: Microsoft Technology Licensing, LLC, Redmond, WA (US)

(72) Inventor: Brandon Aaron RUBENSTEIN, Lynnwood, WA (US)

(21) Appl. No.: 14/872,835

(22) Filed: Oct. 1, 2015

(51) Int. Cl. H05K 7/20; H05K 1/18; H05K 1/02

(52) U.S. Cl. CPC H05K 7/20145; H05K 1/0203; H05K 1/18

(57) ABSTRACT

Baffles separate cooling air into layers and then reduce or prevent mixing of cooling air with air that has been heated by thermal contact with electronic components mounted on a printed circuit board (PCB). Some baffles include an exhaust chamber surface with an exhaust outlet and at least one passage exit. A plurality of cooling chamber surfaces define cooling chambers. Each cooling chamber surface has an inlet for cooling air, an electronics component threshold for pulling heat into the air from the electronic components, and at least one exhaust for heated air. Exhaust passages may connect a cooling chamber to the exhaust chamber; cooling chambers may also exhaust warmed air directly. Chamber surfaces may be parallel, or angled, relative to the PCB. Thresholds may be open, or closed but thermally conductive. Moving parts are not necessarily required in a baffle. Air temperature and flow may be sensed and acted upon.

### BACKGROUND

In operation, electronic components mounted on a printed circuit board or other substrate tend to produce heat. Many electronic components will behave erratically or fail entirely if they get too hot, so attention has been devoted to ways to cool them. Familiar cooling technologies include a wide variety of approaches to air cooling, passive cooling, and liquid cooling, in addition to efforts to reduce the amount of heat produced by electronic components.

### SUMMARY

Some embodiments are directed to the technical activity of managing airflow to help cool electronic components. Some embodiments are directed to the related technical activity of specifying air baffle structure characteristics and features. Other technical activities pertinent to teachings herein will also become apparent to those of skill in the art.

Some embodiments provide tools and/or techniques for managing airflow over a printed circuit board (PCB), the PCB having electronic components mounted in at least groups on a component side of the PCB. Some approaches separate an incoming stream of cooling air into cooling layers on the component side of the PCB. They also direct cooling air from each cooling layer toward at least one respective group of electronic components and then to an exhaust region, while permitting at most an insignificant amount of mixing between cooling layer air which has been directed toward electronic components and carried heat away from them, and cooling air which has not yet been directed toward electronic components.

Some baffles may include at least one exhaust chamber surface which defines an exhaust chamber. The exhaust chamber surface has an exhaust outlet and at least one passage exit. These baffles may also include a plurality of cooling chamber surfaces which define cooling chambers. Each of these cooling chamber surfaces has an inlet, an electronics component threshold, and at least one passage entry. These baffles may also include at least one passage surface. Each passage surface defines a passage which connects to one of the cooling chambers at the passage's entry and connects to the exhaust chamber at the passage's exit.

The examples given are merely illustrative. This Summary is not intended to identify key features or essential features of the claimed subject matter, nor is it intended to be used to limit the scope of the claimed subject matter. Rather, this Summary is provided to introduce—in a simplified form—some technical concepts that are further described below in the Detailed Description. The innovation is defined with claims, and to the extent this Summary conflicts with the claims, the claims should prevail.

### DESCRIPTION OF THE DRAWINGS

A more particular description will be given with reference to the attached drawings. These drawings only illustrate selected aspects and thus do not fully determine coverage or scope.

FIG. 1 is a block diagram illustrating a system having at least one electronic component mounted on at least one printed circuit board or other substrate in an operating environment;

FIG. 2 is a diagram illustrating an open airflow architecture, in contrast with multilayered architectures presented herein;

FIG. 3 is a diagram illustrating a closed single-layer airflow architecture, in contrast with multilayered architectures presented herein;

FIG. 4 is an airflow diagram illustrating airflow in an example architecture which has multiple cooling layers with openings to electronic components, and an exit through one exhaust layer plus one of the cooling layers;

FIG. 5 is an airflow diagram illustrating airflow in an example architecture which has multiple cooling layers with openings to electronic components, and an exit solely through an exhaust layer;

FIG. 6 is an airflow diagram illustrating airflow in an example architecture which has multiple cooling layers with thermally conductive threshold materials next to electronic components, and an exit through one exhaust layer plus one of the cooling layers;

FIG. 7 is an airflow diagram illustrating airflow in an example architecture which has multiple cooling layers with openings to some electronic components and airflow-closed but thermally conductive thresholds next to other electronic components, and an exit through two exhaust layers;

FIG. 8 is a flow chart illustrating aspects of some airflow management processes;

FIG. 9 is a thermal connectivity diagram illustrating a baffle architecture having three cooling chambers, two of which connect to an exhaust chamber for heated air exit and one of which exits directly without going through the exhaust chamber;

FIG. 10 is a perspective view illustrating an airflow passage which has an entry and also has an exit that is larger in cross-sectional area than the entry;

FIG. 11 is a perspective view illustrating a PCB with electronic components mounted on it;

FIG. 12 is a perspective view illustrating the PCB and mounted electronic components of FIG. 11 after the PCB has been attached to a chassis;

FIG. 13 is a perspective view illustrating the PCB, mounted electronic components, and chassis of FIG. 12 with a baffle, before the baffle is attached to the PCB and/or the chassis;

FIG. 14 is a perspective view illustrating airflow after the baffle of FIG. 13 is attached to the PCB and/or chassis;

FIG. 15 is a perspective view illustrating a non-planar cooling chamber surface and two connected passage surfaces;

FIG. 16 is a partial side sectional and perspective view illustrating airflow through baffles attached on opposite sides of a PCB (for clarity, the PCB and electronic components are not shown);

FIG. 17 is a side sectional view illustrating airflow through a baffle architecture which has three cooling layers, planar cooling surfaces oriented at an acute angle to a PCB, openings to electronic components, and an exit through both an exhaust layer and one of the cooling layers;

FIG. 18 is a side sectional view illustrating airflow through a baffle architecture which has three cooling layers, planar cooling surfaces oriented at an acute angle to a PCB, openings to electronic components, and an exit solely through an exhaust layer (insignificant leakage may also occur); and

FIG. 19 is a side sectional view illustrating airflow through a baffle architecture which has three cooling layers, planar cooling surfaces which are parallel to a PCB and have curved portions to direct air and/or reduce turbulence, openings to electronic components, and an exit through both an exhaust layer and one of the cooling layers.

### DETAILED DESCRIPTION

### Acronyms

Some acronyms are defined below, but others may be defined elsewhere herein or require no definition to be understood by one of skill.

CD: compact disc

DVD: digital versatile disk or digital video disc

RAM: random access memory

ROM: read only memory

Overview

Electronic components within an enclosure are often located in such a fashion that there are multiple objects in series in the airflow path. The last object in the series of components receives air that has been preheated by all the upstream components, making it more difficult to cool.

Some embodiments presented herein include or enable a method for distributing fresh air to downstream components and limiting hot and cool air mixing by using airflow management ducting. Cool air is separated into layers. The first layer is exposed to the most upstream components. At the point that air is excessively heated, it is directed to the bottom layer. The air in the next layer of separation is then exposed to the next set of components, heated and directed to the bottom layer. This pattern is continued to the last row of components. At the end of the airstream, the bottom layer is exhausted from the enclosure. This can provide fresh air cooling to each heating device in a row in line with the airflow path.

Some examples presented herein are compatible with, and can supplement, previous solutions. Some examples of complementary previous solutions are using heat sinks on the components, and using airflow vanes to accelerate the flow on the device. Some previous approaches provided some level of fresh air to rear components with ducting, but didn't avoid mixing fresh cooling air with the heated air.

Some baffles presented herein direct fresh air to downstream components while avoiding mixing with air that has been preheated by electronic components upstream. This is accomplished by separating the incoming fresh air stream into sections (also referred to as “layers”). The upper section is the first to be exposed to the hot components on the board. When that air is no longer able to sufficiently cool the components, it is directed to the bottom section through a series of ports/ducts (also referred to as “passages”). The second section is then exposed to the subsequent group of electronic components. When the air in that section absorbs enough heat, it is redirected to the bottom section through another set of passages. This pattern continues until the final electronic component is heated by the second to lowest section. The heated air from the final component is released to the rest of the collected hot air in the bottom section and the air is released from the enclosure.

Thus, solutions are presented for cooling several heated devices in line with the airflow path. Some solutions provide unmixed fresh air to each device in the row; some inhibit or prevent mixing of the heated air and the fresh air.

An original context for one embodiment was cooling requirements for an M.2 card deployment for the PCBs loaded with memory chips in an internally proposed Azure™ Extreme Storage offering (mark of Microsoft Corporation). A simulation suggested up to 20% reduction in heat as compared to an open airflow architecture. However, teachings herein are not limited to PCBs with memory chips alone; indeed, the electronic components being cooled as taught herein need not include any memory chips. Likewise, the teachings are not limited to computer systems which have a processor and memory; the electronic components need not include any processors. Indeed, the system being cooled may be something other than a computer, e.g., it could be composed of electromechanical components or consist in part or entirely of analog circuitry. Moreover, the electronic components being cooled as taught herein need not be arranged in rows or another geometric pattern; baffle openings can be positioned in a PCB-layout-specific arrangement to match the layout of some (or all) of the electronic components on a particular board.

The technical character of embodiments described herein will be apparent to one of ordinary skill in the art, and will also be apparent in several ways to a wide range of attentive readers. For instance, some embodiments address technical activities such as the activity of managing airflow to maintain electronic components within an acceptable operating temperature range, and the activity of monitoring the airflow and/or the temperature within a system.

Reference will now be made to exemplary embodiments such as those illustrated in the drawings, and specific language will be used herein to describe the same. But alterations and further modifications of the features illustrated herein, and additional technical applications of the abstract principles illustrated by particular embodiments herein, which would occur to one skilled in the relevant art(s) and having possession of this disclosure, should be considered within the scope of the claims.

The meaning of terms is clarified in this disclosure, so the claims should be read with careful attention to these clarifications. Specific examples are given, but those of skill in the relevant art(s) will understand that other examples may also fall within the meaning of the terms used, and within the scope of one or more claims. Terms do not necessarily have the same meaning here that they have in general usage (particularly in non-technical usage), or in the usage of a particular industry, or in a particular dictionary or set of dictionaries. Reference numerals may be used with various phrasings, to help show the breadth of a term. Omission of a reference numeral from a given piece of text does not necessarily mean that the content of a Figure is not being discussed by the text. The inventor asserts and exercises his right to his own lexicography. Quoted terms are being defined explicitly, but a term may also be defined implicitly without using quotation marks. Terms may be defined, either explicitly or implicitly, here in the Detailed Description and/or elsewhere in the application file.

Some of the many examples of “electronic components” as that term is used herein include semiconductors (processors, memory, and others), storage devices (magnetic disks, optical disks, tape drives, solid state devices, and others), display devices (light emitting diodes, liquid crystal displays, and others), electromechanical devices (relays, solenoids, piezoelectrics, and others), oscillators, crystals, amplifiers, resistors, capacitors, transformers, transducers, modulators, analog-to-digital converters, sensors, integrated circuits, various analog and/or digital circuits, as well as associated buses, heat sinks, traces, vias, and other circuitry. Electronic components are often mounted on one or more printed circuit boards (PCBs). Although distinctions can be made between rigid PCBs, wire-wrap boards, printed electronics, and organic electronics, for convenience the term “PCB” is used broadly herein to cover them all, and the electronic components are said to be “mounted” on the PCB regardless of whether surface mount technology, in-place printing, or another technology is used to mechanically attach the electronic components to the PCB. Components internal to a PCB substrate are considered to be mounted on whichever side of the PCB they emit the most heat toward. PCBs are also sometimes referred to herein as “boards” but flexible substrates with embedded, printed, or otherwise mounted electronic components are also within the scope of “PCB” and “board” as used herein.

A “system” may be a computer system by virtue of having at least one processor and memory. But a given system may also be free of processors, free of memory, or free of both, yet still be a “system” as that term is used herein.

As used herein, a “computer system” may include, for example, one or more servers, motherboards, other printed circuit boards, processing nodes, laptop computers, tablets, personal computers (portable or not), personal digital assistants, smartphones, smartwatches, smartbands, cell or mobile phones, other mobile devices having at least a processor and a memory, and/or other device(s) providing one or more processors controlled at least in part by instructions. The instructions may be in the form of firmware or other software in memory and/or specialized circuitry. A “multithreaded” computer system is a computer system which supports multiple execution threads. The term “thread” should be understood to include any code capable of or subject to scheduling and/or synchronization.

A “logical processor” or “processor” is a single independent hardware thread-processing unit, such as a core in a simultaneous multithreading implementation. As another example, a hyperthreaded quad core chip running two threads per core has eight logical processors. A logical processor includes hardware. The term “logical” is used to prevent a mistaken conclusion that a given chip has at most one processor; “logical processor” and “processor” are used interchangeably herein. Processors may be general purpose, or they may be tailored for specific uses such as graphics processing, signal processing, floating-point arithmetic processing, encryption, I/O processing, and so on.

A “multiprocessor” computer system is a computer system which has multiple logical processors. Multiprocessor environments occur in various configurations. In a given configuration, all of the processors may be functionally equal, whereas in another configuration some processors may differ from other processors by virtue of having different hardware capabilities, different software assignments, or both. Depending on the configuration, processors may be tightly coupled to each other on a single bus, or they may be loosely coupled. In some configurations the processors share a central memory, in some they each have their own local memory, and in some configurations both shared and local memories are present.

“Kernels” include operating systems, hypervisors, virtual machines, BIOS code, and similar hardware interface software.

“Code” means processor instructions, data (which includes constants, variables, and data structures), or both instructions and data. Some examples include applications, kernels, drivers, interrupt handlers, firmware, state machines, libraries, functions, procedures, controller portions implemented in software, and exception handlers.

“IoT” or “Internet of Things” means any networked collection of addressable embedded computing nodes. Such nodes are examples of computer systems as defined herein, but they also have at least two of the following characteristics: (a) no local human-readable display; (b) no local keyboard; (c) the primary source of input is sensors that track sources of non-linguistic data; (d) no local rotational disk storage—RAM chips or ROM chips provide the only local memory; (e) no CD or DVD drive; (f) embedment in a household appliance; (g) embedment in an implanted medical device; (h) embedment in a vehicle; (i) embedment in a process automation control system; or (j) a design focused on one of the following: environmental monitoring, civic infrastructure monitoring, industrial equipment monitoring, energy usage monitoring, human or animal health monitoring, or physical transportation system monitoring.

As used herein, “include” allows additional elements (i.e., includes means comprises) unless otherwise stated. “Consists of” means consists essentially of, or consists entirely of. X consists essentially of Y when the non-Y part of X, if any, can be freely altered, removed, and/or added without altering the functionality of claimed embodiments so far as a claim in question is concerned.

“Process” is sometimes used herein as a term of the computing science arts, and in that technical sense encompasses resource users, namely, coroutines, threads, tasks, interrupt handlers, application processes, kernel processes, procedures, and object methods, for example. “Process” is also used herein as a patent law term of art, e.g., in describing a process claim as opposed to a system claim. Similarly, “method” is used herein at times as a technical term in the computing science arts and also as a patent law term of art (a process). Those of skill will understand which meaning is intended in a particular instance, and will also understand that a given claimed process or method (in the patent law sense) may sometimes be implemented using one or more processes or methods (in the computing science sense).

Throughout this document, use of the optional plural “(s)”, “(es)”, or “(ies)” means that one or more of the indicated feature is present. For example, “layer(s)” means “one or more layers” or equivalently “at least one layer”.

For the purposes of United States law and practice, use of the word “step” herein, in the claims or elsewhere, is not intended to invoke means-plus-function, step-plus-function, or 35 United State Code Section 112 Sixth Paragraph/Section 112(f) claim interpretation. Any presumption to that effect is hereby explicitly rebutted. Claim language intended to be interpreted as means-plus-function language, if any, will expressly recite that intention.

Throughout this document, unless expressly stated otherwise any reference to a step in a process presumes that the step may be performed directly by a party of interest and/or performed indirectly by the party through intervening mechanisms and/or intervening entities, and still lie within the scope of the step. That is, direct performance of the step by the party of interest is not required unless direct performance is an expressly stated requirement. For example, a step involving action by a party of interest such as achieving, allowing, avoiding, contacting, cooling, directing, exhausting, heating, inhibiting, mixing, permitting, sensing, separating, (and achieves achieved, allows, allowed, etc.) with regard to a destination or other subject may involve intervening action by some other party, yet still be understood as being performed directly by the party of interest.

Whenever reference is made to data or instructions, it is understood that these items configure a computer-readable memory and/or computer-readable storage medium, thereby transforming it to a particular article, as opposed to simply existing on paper, in a person's mind, or as a mere signal being propagated on a wire, for example. No claim covers a signal per se, an abstract idea per se, or a natural phenomenon per se.

An “embodiment” herein is an example. The term “embodiment” is not interchangeable with “the invention”. Embodiments may freely share or borrow aspects to create other embodiments (provided the result is operable), even if a resulting aspect combination is not explicitly described per se herein. Requiring each and every permitted combination to be explicitly described is unnecessary for one of skill in the art, and would be contrary to policies which recognize that patent specifications are written for readers who are skilled in the art. Formal combinatorial calculations and informal common intuition regarding the number of possible combinations arising from even a small number of combinable features will also indicate that a large number of aspect combinations exist for the aspects described herein. Accordingly, requiring an explicit recitation of each and every combination would be contrary to policies calling for patent specifications to be concise and for readers to be knowledgeable in the technical fields concerned.

Some terms herein are defined in terms of measured values, and more than one cutoff is given, potentially resulting in multiple definitions. Particular values are specified in particular claims. But in the event it is not clear to the designated person of ordinary skill in the art which definition applies, then the definition which appears first in the present application as filed should be used.

Operating Environments

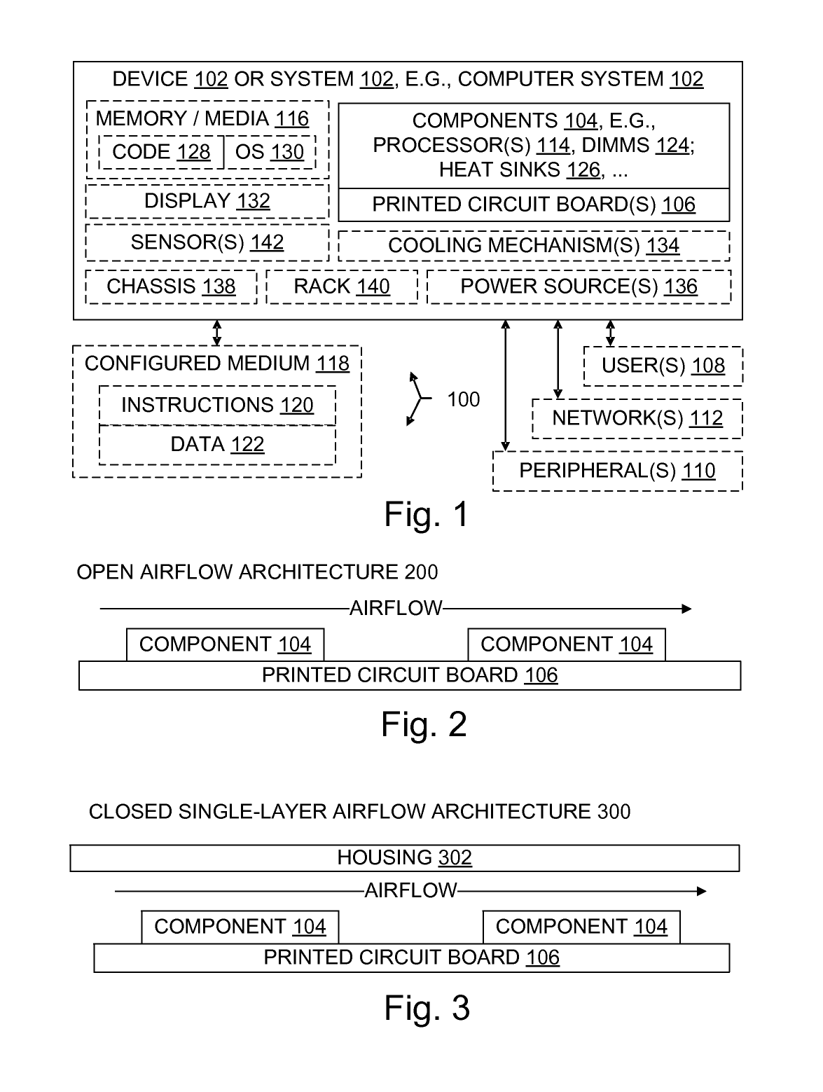

With reference to FIG. 1, an operating environment 100 for an embodiment may include a device 102 or system 102, such as a computer system 102. Devices and systems are each of interest, in that each may contain electronic components 104 mounted on one or more PCBs 106.

A computer system 102 may be a multiprocessor computer system, or not. An operating environment may include one or more machines 102 in a given computer system 102, which may be clustered, client-server networked 112, and/or peer-to-peer networked 112. An individual server or other computing machine is a computer system 102, and a group of cooperating machines is also a computer system.

Human users 108 may interact with the computer system 102 by using displays, keyboards, and other peripherals 110, via typed text, touch, voice, movement, computer vision, gestures, and/or other forms of I/O. A user interface may support interaction between an embodiment and one or more human users. A user interface may include a command line interface, a graphical user interface, natural user interface (gesture recognition, head and eye tracking, motion gesture detection, etc.), voice command interface, augmented reality interface, virtual reality interface, and/or other interface presentations. A given operating environment includes devices 102 and infrastructure (power, network, fans, etc.) which support these different options and uses.

System administrators, developers, engineers, and end-users are each a particular type of user 108. Automated agents, scripts, playback software, and the like acting on behalf of one or more people may also be users 108. Storage devices and/or networking devices may be considered peripheral equipment in some embodiments. An embodiment may be deeply embedded in a technical system, such as a portion of the Internet of Things, such that no human user 108 interacts directly with the embodiment. Other computer systems not shown in FIG. 1 may interact in technological ways with the computer system 102 or with another system embodiment using one or more connections to a network 112 via network interface equipment, for example. Some embodiments operate in a “cloud” computing environment and/or a “cloud” storage environment in which computing services are not owned by their end user but are provided on demand.

A computer system 102 includes at least one logical processor 114. The computer system 102 also includes one or more computer-readable storage media 116. Media 116 may be of different physical types. The media 116 may be volatile memory, non-volatile memory, disks (magnetic, optical, or otherwise), fixed in place media, removable media, magnetic media, optical media, solid-state media, and/or of other types of physical durable storage media (as opposed to merely a propagated signal). In particular, a configured medium 118 such as a portable (i.e., external) hard drive, CD, DVD, memory stick, or other removable non-volatile memory medium may become functionally a technological part of the computer system when inserted or otherwise installed, making its content accessible for interaction with and use by processor 114. The removable configured medium 118 is an example of a computer-readable storage medium 116. Some other examples of computer-readable storage media 116 include built-in RAM, flash memory, EEPROMS or other ROMs, hard disks, and other memory storage devices which are not readily removable by users 108. For compliance with current United States patent requirements, neither a computer-readable medium nor a computer-readable storage medium nor a computer-readable memory is a signal per se.

The medium 118 is configured with instructions 120 that are executable by a processor 114; “executable” is used in a broad sense herein to include machine code, interpretable code, bytecode, and/or code that runs on a virtual machine, for example. The medium 118 is also configured with data 122 which is created, modified, referenced, and/or otherwise used for technical effect by execution of the instructions 120. The instructions 120 and the data 122 configure the memory or other storage medium 118 in which they reside; when that memory or other computer readable storage medium is a functional part of a given computer system, the instructions 120 and data 122 also configure that computer system. Memory 116 may be configured with code 128, such as applications and/or an operating system 130.

Although an embodiment or an operating environment may be described as being implemented as software instructions executed by one or more processors in a computing device (e.g., general purpose computer, cell phone, or gaming console), such description is not meant to exhaust all possibilities. One of skill will understand that the same or similar functionality can also often be implemented, in whole or in part, directly in hardware logic, to provide the same or similar technical effects. Alternatively, or in addition to software implementation, the technical functionality described herein can be performed, at least in part, by one or more hardware logic components. For example, and without excluding other implementations, an embodiment may include hardware logic components such as Field-Programmable Gate Arrays, Application-Specific Integrated Circuits, Application-Specific Standard Products, System-on-a-Chip components, Complex Programmable Logic Devices, and similar electronic components. Components of an embodiment may be grouped into interacting functional modules based on their inputs, outputs, and/or their technical effects, for example.

In some embodiments, a computer system 102 includes multiple computers connected by a network 112. Networking interface equipment can provide access to networks using components such as a packet-switched network interface card, a wireless transceiver, or a telephone network interface, for example, which may be present in a given computer system. However, an embodiment may also communicate through direct memory access, removable nonvolatile media, or other information storage-retrieval and/or transmission approaches, or an embodiment may operate in a computer system without communicating with other computer systems.

In addition to processors 114 (e.g., central processing units, arithmetic and logic units, floating point processing units, and/or graphical processing units), memory/storage media 116, display(s) 132, and battery(ies), an operating environment may also include other hardware, such as dual inline memory modules 124, heat sinks 126, buses, power supplies, wired and wireless network interface cards, and accelerators, for instance, whose respective operations are described herein to the extent not already apparent to one of skill.

Cooling mechanisms 134 may be present, such as air conditioning condensers, fans, raised flooring, thermostats, and ventilation ducts.

Power sources 136 are typically present, but not necessarily local. Examples include connections to a power grid, generators (e.g., diesel-powered, solar, wind, geothermal systems), batteries, and uninterruptible power supplies.

Boards 106 may be mounted in a chassis 138, which may in turn be mounted in a rack 140. The chassis and/or rack may include a housing.

Sensors 142 may be placed inside or near a system to measure temperature, airflow rate, humidity, and/or other environmental variables.

One of skill will appreciate that the foregoing aspects and other aspects presented herein under “Operating Environments” may also form part of a given embodiment. This document's headings are not intended to provide a strict classification of features into embodiment and non-embodiment feature classes. One or more items are shown in outline form in the Figures to emphasize that they are not necessarily part of the illustrated operating environment or all embodiments, but may interoperate with items in the operating environment or some embodiments as discussed herein. It does not follow that items not in outline form are necessarily required, in any Figure or any embodiment. In particular, FIG. 1 is provided for convenience; inclusion of an item in FIG. 1 does not imply that the item, or the described use of the item, was known prior to the current innovations.

Some Earlier Architectures

FIG. 2 illustrates aspects of an open airflow architecture 200. Air is heated as it travels over the component on the left, so the air flowing over the component on the right carries heat from the component on the left. This reduces the effectiveness of passing air over the component on the right to cool it, but is nonetheless an adequate and cost effective approach in some situations. The architecture 200 is open in the sense that no baffle, housing, or other airflow control mechanism is present specifically to keep the airflow near the PCB 106. Indeed, one of the design considerations may have been allowing heated air to move away from the PCB, into a larger space such as a workstation housing, a desktop computer shell, or a rack housing, before it leaves the space defined as the space occupied by all vectors normal to the PCB surface.

In something of a contrast, FIG. 3 shows an architecture 300 which includes a housing 302 that keeps the airflow near the PCB 106, e.g., where “near” may be defined by an absolute measure such as one inch, or by a relative measure such as twice the height of the tallest component on the PCB. Hence, architecture 300 is a closed architecture. Architecture 300 provides only a single layer of airflow, bounded on one side by the housing 302 and on the other side by the components and PCB. As a result, the air flowing over the component on the right still carries heat from the component on the left, as in architecture 200.

Note that these architectures are classified and described in hindsight with the benefit of knowledge of the innovations presented herein. Accordingly, one of skill in the art prior to the present innovations would not necessarily have singled out these architectures or focused on the characteristics discussed here.

Some Airflow Diagrams

An airflow diagram illustrates major locations traversed by air flowing within a system, indicating both where the air flows and where it does not flow. In addition to locations expressly shown in an airflow diagram, other locations (e.g., openings) may be implied by the diagram. One of skill will understand that many specific baffles can conform with a given airflow diagram, because the diagram does not dictate measurements (in either two or three dimensions), chamber or opening or other shapes, air speeds, temperatures, or the materials and methods used in constructing a given baffle.

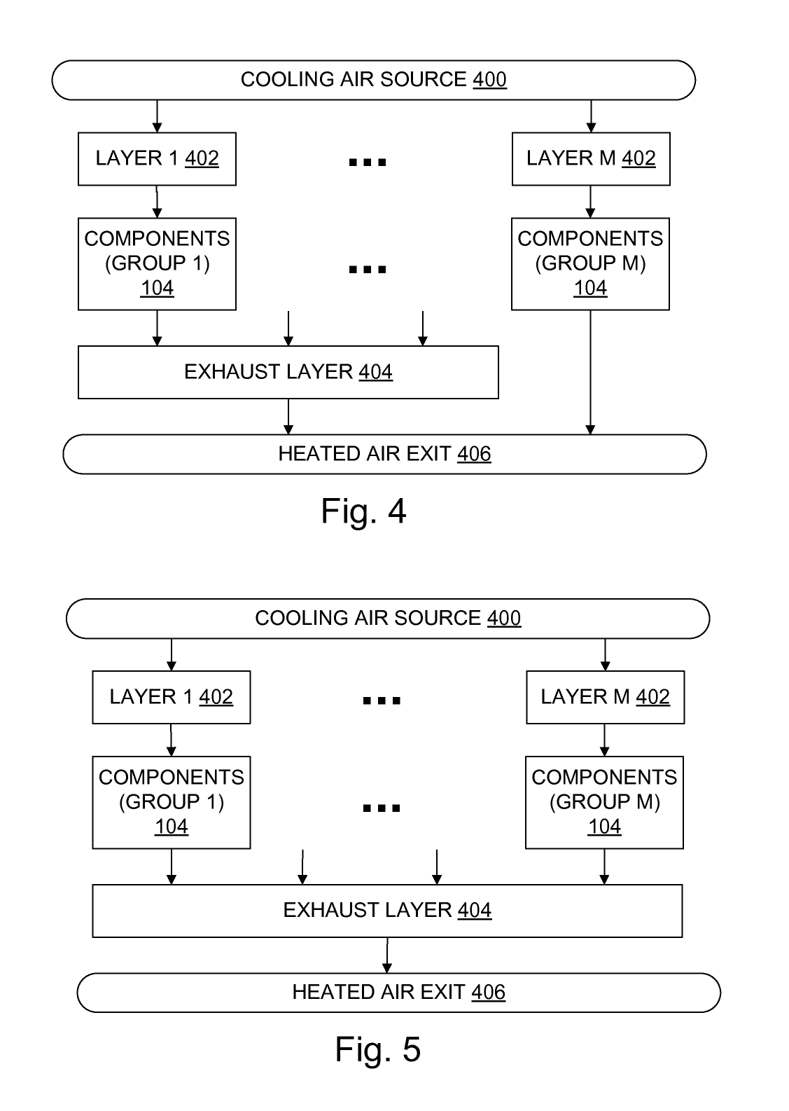

FIGS. 4 through 7 are airflow diagrams illustrating aspects of some architectures presented herein. In these diagrams, the airflow of interest comes from a cooling air source 400, travels through multiple cooling air layers 402, reaches electronic components 104 themselves through threshold openings and/or reaches airtight thresholds made of thermally conductive material 600 that adjoin components 104, may reach an exhaust layer 404, and ultimately reaches a heated air exit 406. Each of the diagrams presented shows between 1 and M cooling layers 402, where M is an integer 2 or greater. The exhaust layer, unlike the cooling layers, does not receive cooled air. Instead, the exhaust layer receives air only after the air has been heated by direct or indirect thermal transfer from at least one electronic component on a PCB. Components 104 may be arranged on the PCB in rows or other groups.

In these diagrams, arrows indicate the direction of air flow. Air may be pushed in that direction by fans located at or prior to the source 400, or pulled in that direction by fans located at or after the exit 406; air may also be both pushed and pulled in a given example.

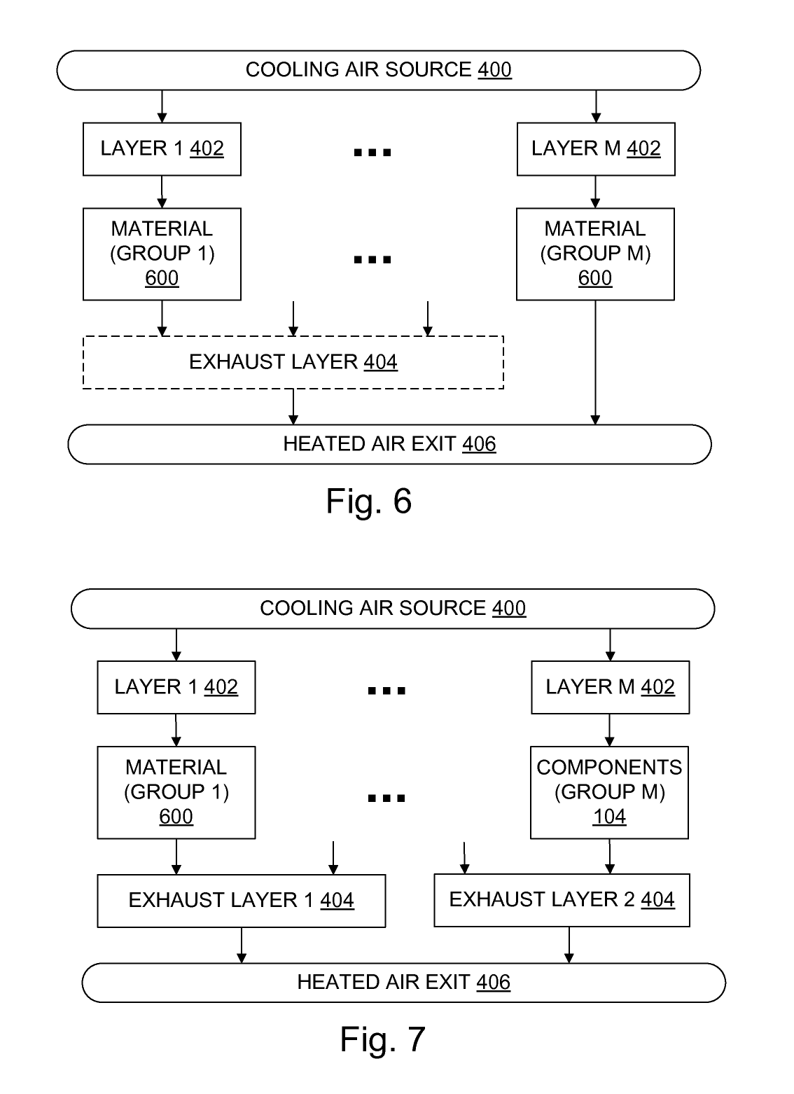

The four diagrams presented are not comprehensive of all baffle architectures taught herein to those of skill in the art. For instance, another architecture which is not shown expressly is nonetheless implicit in FIG. 4, being derived therefrom by omitting exhaust layer 404 so that each layer exhausts warmed air directly from the baffle after cooling that layer's group of components. The optionality of exhaust layers is also indicated by dashed lines in FIG. 6. The diagrams illustrate particular aspects, including the separate nature of the cooling air layers. Air does not flow between layers, at least not in any thermally significant amount. These diagrams also illustrate the presence of zero or more openings in a cooling layer's surface to let cooling air contact electronic components directly, with the possibility of increased leakage. Openings are in contrast with the use of zero or more closed but thermally conductive thresholds to reduce or prevent air leakage at the cost of reduced cooling, since the heat from the components travels through the threshold material before reaching the cooling air. The diagrams also illustrate exit options, e.g., sending all air through a single exhaust layer to exit, sending air through two or more exhaust layers, or sending air through both the exhaust layer(s) and one of the cooling layers.

With the foregoing in mind, FIG. 4 illustrates airflow in an example architecture which has multiple cooling layers 402 with openings to electronic components 104. The heated air exits through one exhaust layer plus some heated air exits directly from one of the cooling layers.

FIG. 5 illustrates airflow in a different architecture. It still has multiple cooling layers 402 with openings to electronic components, but the heated air exits solely (insignificant leakage aside) through an exhaust layer 404.

FIG. 6 illustrates airflow in an architecture which—like the others illustrated here—has multiple cooling layers 402. Instead of openings to let air reach the components 104, however, the air flows against thermally conductive threshold material 600 to pull or accept heat from underlying electronic components. In this architecture, heated air exits through one exhaust layer except for a direct exit from one of the cooling layers (typically but not necessarily the one physically farthest from the source 400).

FIG. 7 illustrates airflow in an architecture which has multiple cooling layers 402, including some with openings to some electronic components and some with thermally conductive threshold material 600 to other electronic components. Heated air exits through two exhaust layers 404.

Materials used in surfaces that separate the layers 402 of air flow or otherwise constrain airflow may include, for example plastic, metal, glass, epoxy, natural or artificial rubber, or carbon-based materials. Thermally conductive threshold materials 600 may include, for example, silica-based and other glasses, carbon nanotubes, beryllium oxide, or other materials, with an emphasis on materials that are electrically insulative and thermally conductive when the electrical components include integrated circuits or other electronics. One of skill will balance molding/casting/extruding/shaping/machining feasibility, cost, thermal conductivity, and other familiar factors in a given situation to select baffle materials and baffle manufacturing methods without undue difficulty, in view of the teachings herein.

Processes

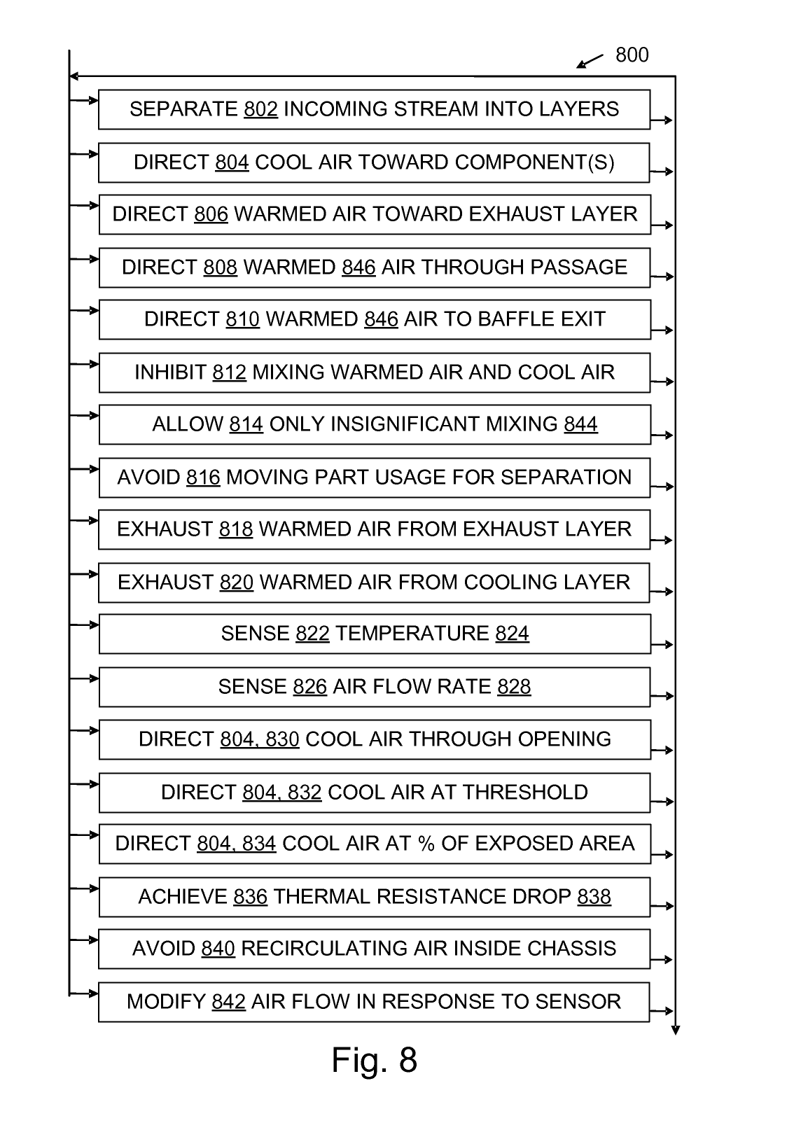

FIG. 8 illustrates some process embodiments in a flowchart 800. Technical processes shown in the Figures or otherwise disclosed may be performed in some embodiments automatically, e.g., by a baffle with no moving parts. Processes may also be performed in part automatically and in part manually unless otherwise indicated. In a given embodiment zero or more illustrated steps of a process may be repeated, perhaps with different parameters or data to operate on. Steps in an embodiment may also be done in a different order than the top-to-bottom order that is laid out in FIG. 8. Steps may be performed serially, in a partially overlapping manner, or fully in parallel. The order in which flowchart 800 is traversed to indicate the steps performed during a process may vary from one performance of the process to another performance of the process. The flowchart traversal order may also vary from one process embodiment to another process embodiment. Steps may also be omitted, combined, renamed, regrouped, or otherwise depart from the illustrated flow, provided that the process performed is operable and conforms to at least one claim.

Examples are provided herein to help illustrate aspects of the technology, but the examples given within this document do not describe all possible embodiments. Embodiments are not limited to the specific shapes, layer counts, materials, names, implementations, arrangements, figures, features, approaches, or scenarios provided herein. A given embodiment may include additional or different technical features, mechanisms, and/or steps, for instance, and may otherwise depart from the examples provided herein.

Some embodiments provide or utilize a method of managing airflow over a printed circuit board (PCB) 106. The PCB 106 has electronic components 104 mounted in at least N groups on a component side of the PCB, with N being at least 2. In some configurations, the PCB has two component sides, i.e., electronic components 104 are mounted on both sides of the PCB. One method includes separating 802 an incoming stream of cooling air into at least M cooling layers 402 on the component side of the PCB, with M being at least 2. Then cooling air from each cooling layer is directed 804 toward at least one respective group of electronic components and then directed 806 to an exhaust layer 404. The method permits 814 at most an insignificant amount of mixing between cooling layer air which has been directed toward electronic components and carried heat away from them, and cooling air which has not yet been directed toward electronic components. In one example, the amount of mixing is deemed insignificant if it contributes a rise in each cooling layer air temperature of less than one-half of one degree Celsius. In another, the cutoff for mixing to be deemed insignificant is one degree Celsius. Leakage may be considered a form of mixing, albeit with air outside the baffle, so the definitions of insignificant mixing may also be applied to determine whether leakage from the baffle is deemed insignificant.

In some embodiments, the directing 804 directs cooling air from each cooling layer toward a single respective row of electronic components 104 which are mounted on the PCB, and then directs 806 the warmed air to the exhaust layer. In some embodiments, cooling air is directed 804, 830 through an opening near the electronic components, as illustrated for instance in FIGS. 4 and 5. In some embodiments, cooling air is directed 804, 832 at a threshold which is airtight (allowing at most insignificant leakage) but in thermal communication with the electronic components, as illustrated for instance in FIG. 6. In some embodiments, a PCB has electronic components mounted in at least N groups on a component side of the PCB, with each row oriented at an angle between 45 degrees and 135 degrees to an incoming stream of cooling air, N being at least 2. In some other embodiments, the electronic components are not mounted in rows.

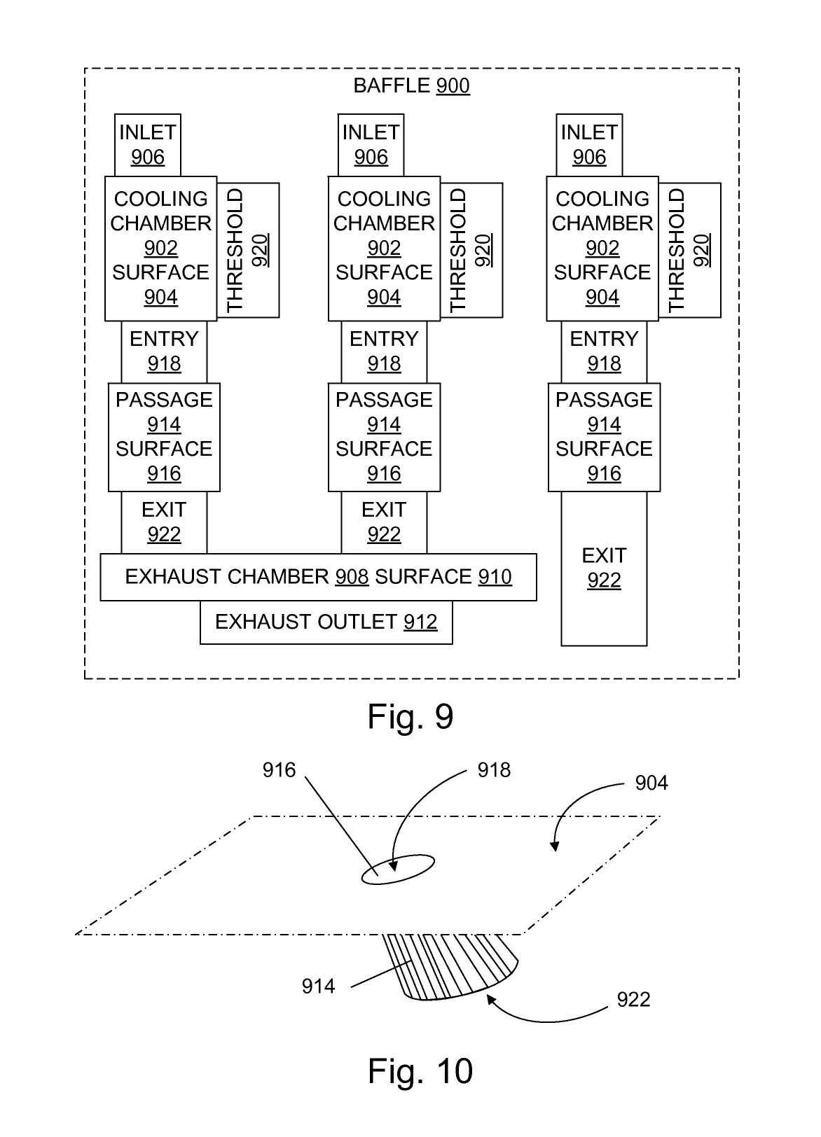

In some embodiments, the directing 806 directs air from a cooling layer to the exhaust layer by directing 808 the heated air through an enclosed passage from the cooling layer to the exhaust layer. Using an enclosed passage helps reduce or prevent mixing of cooled and heated air. Passages are discussed further in connection with FIGS. 9 and 10, for example.

In some embodiments, the separating 802 produces a separation of the incoming stream of cooling air into layers 402 without relying (e.g., while avoiding 816) on any moving parts to produce the separation. Nominal presence of a moving part which impacts less than five percent of air flow rate is deemed non-reliance.

In some embodiments, the PCB 106 is mounted in a chassis 138, and the method avoids 840 bringing air which has been directed 804 over electronic components 104 that are mounted on the PCB and into 806 the exhaust layer back into thermal contact with the same or other electronic components 104 mounted on the PCB until after the air has been exhausted 810 from the baffle and the chassis. That is, the method avoids 840 recirculating the air inside the chassis (or in some cases, inside a rack 140).

In some embodiments, air is exhausted 818 from the chassis from the exhaust layer and is also exhausted 820 directly from the chassis from exactly one of the cooling layers. This is illustrated, e.g., in FIGS. 4 and 6. The cooling layer which exhausts directly instead of via the exhaust layer may be, for example, the cooling layer which has the longest path traveled by cooling air from a point at which the separating 802 into layers occurs to a point at which air in the cooling layer carries heat away from electronic components.

Some embodiments sense 822 a temperature 824 indication, either as a value in degrees or as a velocity of temperature change. Some embodiments sense 826 an air flow rate 828. Some embodiments sense at least one of the following items, and then modify 842 air flow rate, temperature, and/or direction in response to the sensed item(s): a temperature of air which has been directed over electronic components mounted on the PCB, a temperature at a location on the PCB, a temperature of a component which is mounted on the PCB, a rate of temperature change, an air flow rate over a location on the PCB, or an air flow rate over a component which is mounted on the PCB. For instance, sensing a temperature above a predefined value and/or rising at faster than a predefined rate at a location may cause modification in the form of adding fans, speeding up fans, or redirecting additional cooling air to the location.

In some embodiments, a method of managing airflow over a printed circuit board (PCB) includes separating 802 an incoming stream of cooling air into at least two layers of cooling air on a component side of the PCB, and directing 804 cooling air from each layer over a respective set of one or more electronic components 104 mounted on the PCB and then through 808 at least one enclosed passage to an exhaust region, thereby cooling the electronic components. This method also inhibits 812 mixing 844 between air which has been directed over electronic components and air which has not. In some embodiments, inhibiting 812 mixing occurs when mixing 844 contributes a rise in cooling layer air temperature of at most one degree Celsius for each cooling layer. In some, inhibiting 812 mixing occurs when a flow rate of mixing air from a cooling layer is less than five percent of an overall flow rate from the cooling layer for each cooling layer.

In some embodiments, the method includes directing 804, 834 cooling air over at least 90% of the total exposed surface area of the electronic components mounted on the PCB. In some, the method includes directing 804, 834 cooling air over at least 60% of the sum of (a) total exposed surface area of the electronic components mounted on the PCB, and (b) total exposed surface area of a side of the PCB on which the electronic components are mounted.

In some embodiments, the method includes achieving 836 at least a 6 degrees Celsius per Watt drop in thermal resistance 838 during powered operation of at least one electronic component mounted on the PCB when compared to powered operation of the same electronic component(s) without the separating and directing steps. In some embodiments, at least a 9 degrees Celsius per Watt drop is achieved 836, and in some a drop of at least 11 degrees Celsius per Watt is achieved 836. These values are in range for results predicted by computational dynamic fluid flow simulation; results in a given implementation may vary. Thermal resistance is defined as the delta in degrees Celsius (or Kelvin, since the delta between degrees is the same) divided by Watts of power.

In some embodiments, the exhaust region includes an exhaust layer into which at least one enclosed passage exhausts heated air and the exhaust region also includes a layer direct exit region at a layer's end. This is illustrated, for example in FIGS. 4, 6, 17, and 19. In other embodiments, exhaust is only through the exhaust layer, as illustrated for example in FIGS. 5 and 18. In others, no exhaust layer is present and the separated unmixed heated air exits into the exhaust region directly from the cooling layers, as shown for instance in FIG. 16.

FIG. 9 is a thermal connectivity diagram illustrating a baffle 900 architecture. The illustrated architecture is a three-layer architecture, but one of skill will readily apply this example to obtain baffles having two layers 402, four layers 402, five layers 402, or more. Adding layers 402 generally introduces drag and turbulence, thus reducing overall airflow velocity, but offers improved cooling capabilities in some situations that apply the teachings provided herein. A given cooling layer 402 corresponds to air within a cooling chamber 902. Each cooling chamber 902 is defined by a surface 904 which has at least one inlet 906 aperture. Each cooling chamber also has a threshold 920, in the form of one or more openings and/or thermally conductive material 600. As illustrated by FIG. 15, the surface 904 defining the cooling chamber 902 is not necessarily planar.

The illustrated baffle 900 also has an exhaust chamber 908 defined by a surface 910. The exhaust chamber has an outlet 912 aperture, which serves as a heated air exit 406. The exhaust layer 404 corresponds to air within exhaust chamber 908.

Two of the illustrated cooling chambers 902 are connected with the exhaust chamber 908 for airflow by way of one or more passages 914. Each passage 914 is defined by a surface 916, which has apertures in the form of an entry 918 and an exit 922. As illustrated by FIG. 15, the surface 916 may have an ovoid cylindrical shape, for example. The third cooling chamber in the illustrated architecture of FIG. 9 also connects to a passage 914, but this passage provides a direct exit 922, 406 for heated air, rather than directing the heated air to the exhaust chamber 908.

FIG. 10 illustrates an airflow passage 914 which has an entry 918 and also has an exit 922 that is larger in cross-sectional area than the entry. This may assist airflow through the passage. A given embodiment may include passages of uniform cross-sectional area, passages of increasing cross-sectional area as shown in FIG. 10, or a mixture of such passages. Other passage dimensions and/or shapes may also be used. For instance, passage cross-sections may be circular or otherwise ovoid, square or rectangular or otherwise polygonal, or irregularly shaped.

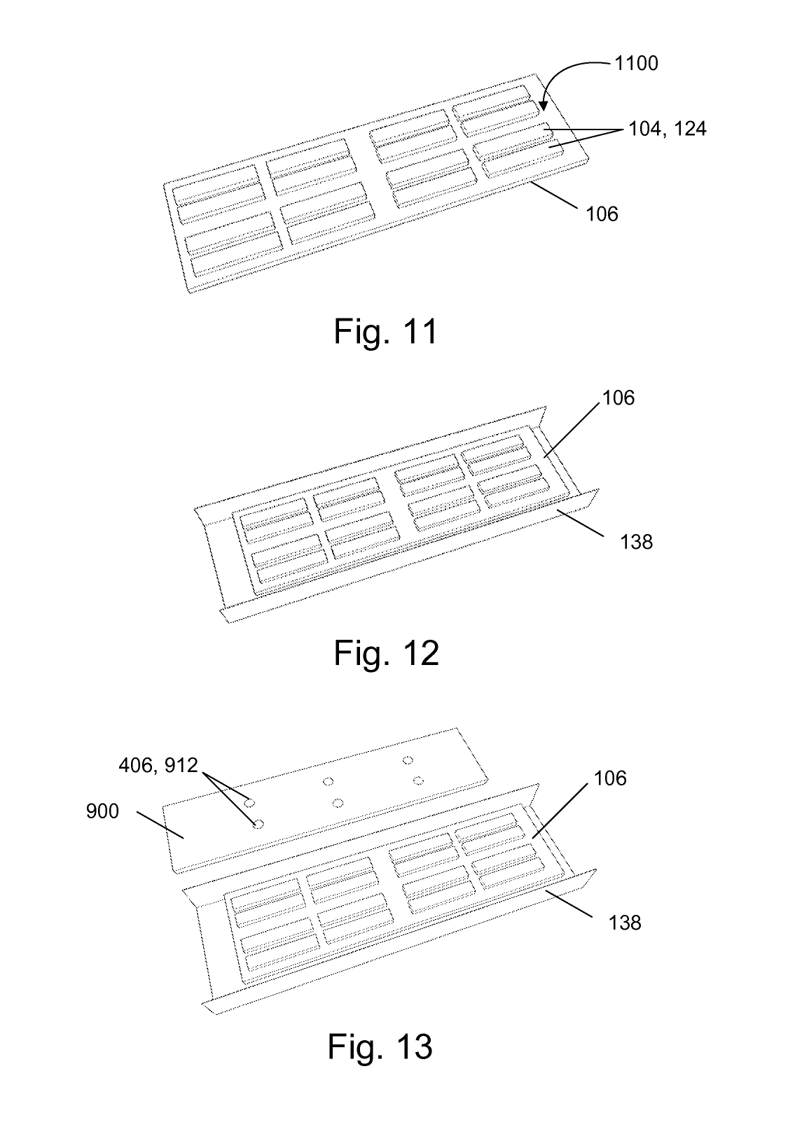

FIG. 11 shows an example of a PCB 106, including mounted electronic components 104 in the form of memory cards 124 arranged in an array on a component side 1100 of the PCB. Each memory card may itself include a printed circuit card attached through a connector to the main PCB 1100, and may also include a memory module, e.g., a dual inline memory module (DIMM). As illustrated in FIG. 12, these assemblies 124 are placed into a computer chassis.

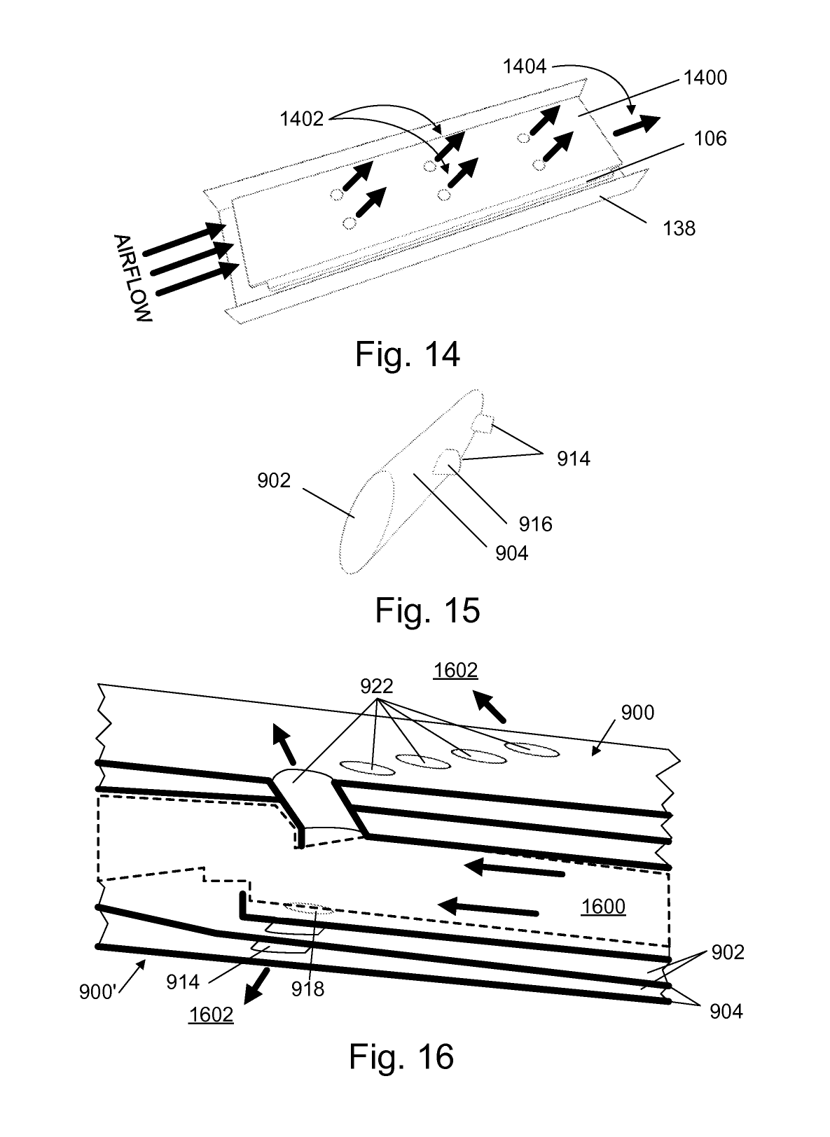

FIG. 13 shows a baffle 900, also referred to as an airflow baffle assembly, which will be placed around the array of boards 124 to help provide airflow guidance. This baffle is oriented with the exhaust layer closest to the viewer, and thus farthest from the main PCB 106. Exhaust outlets 912 are visible, as part of a baffle exit 406 for heated air to be exhausted 818 as shown in FIG. 14.

Thus, in operation cooling air enters this baffle 900 as indicated by the three airflow arrows near the label “AIRFLOW” in FIG. 14, and is separated 802 into cooling layers. The separated cooling air layers are directed 894 toward respective rows of memory cards 104, 124 where heat is transferred from the cards to the air. The warmed air is then directed 808 from some of the cooling layers through internal passages (not shown here but see, e.g., FIGS. 9, 10, 15, 16, 17, 18, 19) to an exhaust chamber 908, from which it exhausts 818 through the outlets 912 in the baffle exterior 1400 as indicated, e.g., by the airflow arrows 1402. Heated air is also exhausted 820 from one of the cooling layers of the baffle 900, as indicated by the airflow arrow 1404.

One effect of the illustrated baffle 900 is to direct fresh cool air to downstream components 104 while avoiding 840 mixing fresh air with air that has been preheated 846 by components 104 upstream (i.e., closer to the AIRFLOW label). This is accomplished by separating 802 the incoming fresh air stream into sections (a.k.a. layers, with the understanding that they may be layered top-to-bottom, side-by-side, or otherwise). In the illustrated baffle 900, an upper section is the first to be exposed to the hot components 104, 124 on the board 106. When that air is no longer able to sufficiently cool the components, it is directed 808 to the bottom section (which serves as an exhaust layer 404) through a series of ports/ducts (in this case, passages 914). The second section 402 is then exposed 804 to the following row of components. When the air in that section absorbs enough heat, it is redirected 808 to the bottom section through another set of ports/ducts/passages. This pattern continues until the final component 104 group heats 846 air in the second to lowest section. The heated air from the final group of components (final row) is released directly 820, consistent with FIGS. 4 and 6. In a variation, heated air from the final row of components is released to the rest of the collected hot air in the bottom section (the exhaust layer) and the air is released 810 from the enclosure.

In some examples, electronic components 104 are mounted on both sides of a PCB 106. In such cases, separated and unmixed cooling air can be directed as taught herein on both sides of the PCB. This may be accomplished with an apparatus in the form of a single baffle 900 that encloses the PCB, or an apparatus in the form of a top baffle 900 in conjunction with a bottom baffle 900, each of which directs cooling air on a respective side of the PCB.

For example, FIG. 16 below shows a partial cross section of an assembly which includes a top baffle 900, a bottom baffle 900′, and a space 1600 for boards in between the baffles, e.g., for a main PCB 106 and memory cards 124 mounted to the main PCB. Circular passages 914 provide volume for the hot air to escape from the surface of the electrical component 104 (not shown) in space 1600 to a nearby exhaust region 1602. There are several passage exits 922 (also called “ports”) in a row in this example, with space between them to allow the fresh air from lower sections to pass around them without undue airflow restriction.

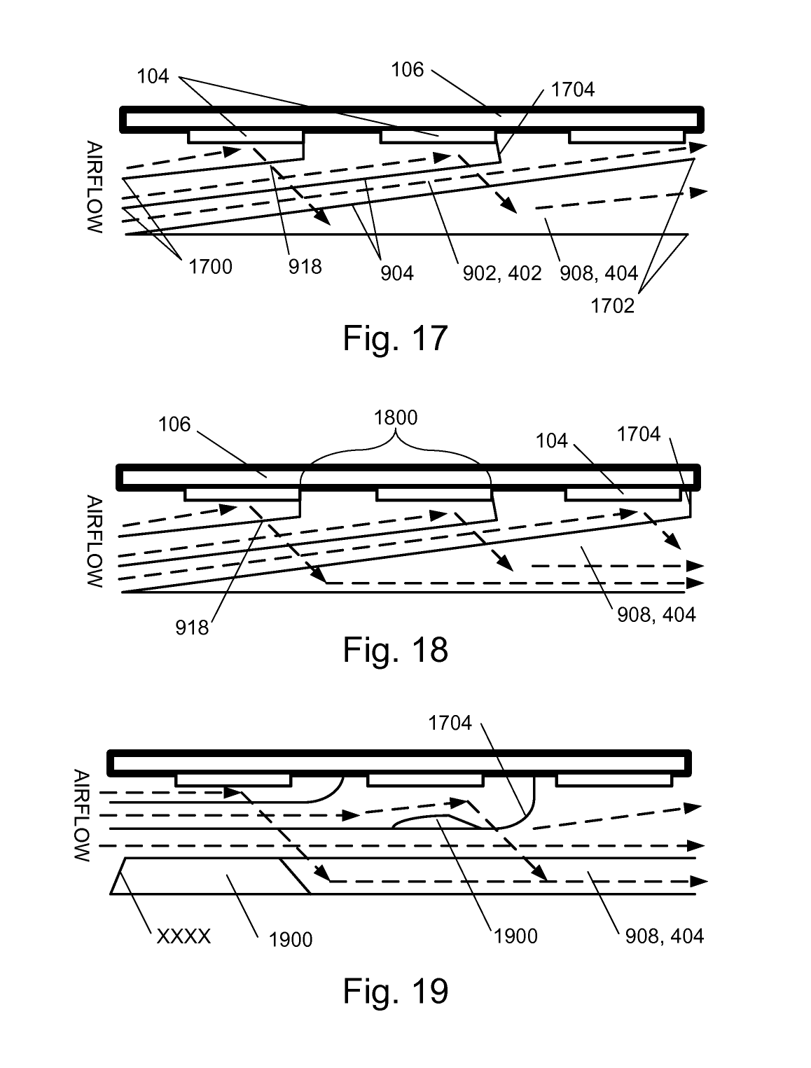

FIGS. 17, 18, and 19 further illustrate the operation of some embodiments. In these Figures, solid lines (other than reference numeral and lead lines) indicate surfaces, namely, layer surfaces, electronic component surfaces, and PCB surfaces. Airflow is indicated by dashed-line arrows, with the understanding that when a dashed-line arrow crosses a solid line the air is flowing through a passage 914.

In operation, cooling air enters at the left (near the AIRFLOW label) and is separated by the layer surfaces' leading edges 1700 into layers. The top layer cools the first component (the leftmost component in this example) and then the heated air is ducted 808 to the lowest layer, the exhaust layer. The duct 914 interiors are physically separated from the layers of fresh air by the duct surfaces 916 and the layer surfaces 904, for instance, thus inhibiting 812 preheating of the lower layers by warmed 846 air. Moving right, the second layer of cooling air is exposed and cools the second (middle in this example) component 104, after which that layer's heated air is ducted 808 to the lowest layer. To facilitate the ducting 808, the layer surface 904 includes a wall 1704 as well as one or more passage entries 918. At the final (rightmost in this example) component 104, the cooling air of the second from lowest layer is exposed to the component. Then that air is merged with the air from the other layers. In the illustrated example, the trailing edges 1702 of the exhaust layer and the layer above it end at the same distance from the leading edges 1700, but in an alternate embodiment the bottom surface 910 extends farther, so the second from lowest layer exhausts into the exhaust layer, but does so directly rather than through a passage.

In the FIG. 17 example, the cooling layer surfaces are planar, in a general sense, as opposed to being cylindrical or spherical, for example. The cooling layer planes are oriented at an acute angle to the plane of the PCB 106. In FIG. 18, the cooling layer surfaces are also planar, and they are also oriented at an acute angle to the plane of the PCB 106. However, in FIG. 18 each cooling layer surface includes a wall 1704 and one or more passage entries 918 to duct heated air into the exhaust chamber 908, instead of having one cooling chamber exhaust heated air without a passage 914 as in FIG. 17. In both FIG. 17 and FIG. 18, however, cooling air is directed 804 at components 104 through openings 1800. For clarity of illustration, only a single opening 1800 is called out in these Figures, but one of skill will understand that multiple openings are present in these examples because multiple cooling layers are present and because the thresholds in these examples are openings that permit air to pass through rather than being closures made of material 600.

FIG. 19 illustrates an example baffle that shares some aspects with the examples in FIGS. 17 and 18, such as separating cooling air into layers and inhibiting or preventing mixing of warmed air with cooling air, and having cooling chamber surfaces that are generally planar. However, in FIG. 18 the cooling layer surfaces are parallel to the plane of the PCB 106, instead of being oriented at an acute angle to the PCB. Also, the example in FIG. 18 includes dead spaces 1900 defined by surfaces that help provide structural strength and/or help direct air flow within the baffle. Also, the walls 1704 are curved instead of being polygonal.

Some embodiments provide or use a baffle 900 which includes at least one exhaust chamber surface 910 which defines an exhaust chamber 908, the exhaust chamber surface having an exhaust outlet 912 and at least one passage exit 922. This baffle also includes a plurality of cooling chamber surfaces 904 which define N cooling chambers 902, N being at least two. Each of these cooling chamber surface has an inlet 906, an electronics component threshold 920, and at least one passage entry 918. This baffle also includes at least one passage surface 916. Each passage surface defines a passage 914 which connects to one of the cooling chambers at the passage's entry and connects to the exhaust chamber at the passage's exit.

Some embodiments include a baffle 900 in combination with and attached to a printed circuit board (PCB) 106. The PCB has electronic components 104 mounted on a component side of the PCB, and the electronic components are positioned adjacent the electronics component thresholds of the baffle. “Adjacent” as used here means in thermal communication such that flowing air through or against the thresholds 920 transfers a measurable amount of thermal energy from the component(s) 104 to the flowing air during a period from ten seconds to one hundred thirty seconds after the flowing air's first contact with the threshold, when the temperature of the flowing air immediately before it contacts the threshold is at least five degrees Celsius less than the surface temperature of the component(s). The baffle may be attached to the PCB by mechanical means (clips, screws, bolts, etc.) and/or by an adhesive, for example. The attachment may be releasable to aid servicing of the baffle and/or the components, or permanent.

In some baffle embodiments, the cooling chamber surfaces include a planar cooling chamber top surface, a planar cooling chamber bottom surface, and side walls connecting the top surface to the bottom surface. In some of these, the cooling chamber top surface and the cooling chamber bottom surface are parallel to the PCB, as shown for instance in FIG. 19. In some, the cooling chamber top surface and the cooling chamber bottom surface are parallel to one another. In some, the cooling chamber top surface and the cooling chamber bottom surface are each at an acute angle to the PCB, as shown for instance in FIGS. 17 and 18.

In some baffle embodiments, at least one electronics component threshold 920 includes an opening through which cooling air can reach an electronics component when the baffle is attached to a printed circuit board on which the electronics component is mounted, as shown for instance in FIGS. 17 and 18. In some embodiments, at least one electronics component threshold 920 includes a thermally conductive material 600 which cooling air can reach and then carry heat away from an electronics component when the baffle is attached to a printed circuit board on which the electronics component is mounted and the thermally conductive material of the electronics component threshold is placed against the electronics component.

In some baffle embodiments, the cross-sectional area of a cooling chamber 902 orthogonal to airflow direction is within a range from 90% to 110% of the total cross-sectional area of passage entries 918 leaving that cooling chamber.

In some baffle embodiments, the cooling chambers 902 connect with one another (as to airflow) inside the baffle 900 only by way of the exhaust chamber 908 and one or more of the passages 914. Accordingly, there is no measurable mixing of cooling air with heated 846 air inside the baffle.

In some baffle embodiments, the cooling chamber surfaces reside on a plurality of pieces which are stacked together to form the baffle before it is placed in operation. The pieces may correspond generally to the layers, for example, and may snap or clip together to be assembled into the baffle 900.

In some embodiments, the baffle is free of moving parts. In others, moving vanes are present, to permit adjustments in airflow direction during use of the baffle for cooling. Adjustments may be made, for example, in response to sensed 822, 826 values.

In some embodiments, at least one passage is further characterized in that the cross-sectional area of the passage entry is smaller than the cross-sectional area of the passage exit. One of the many possible examples is illustrated in FIG. 10.

Fluid flow simulation by the inventor suggests a temperature reduction of up to 20% is possible compared to a solution with no ducting. However, different embodiments will likely provide different respective results.

In some embodiments, the end of the cooling layer engages in a releasable seal with the PCB surface, to reduce or prevent air mixing with the subsequent layer. Opening 1800 edges may accordingly be formed of a flexible plastic, or an artificial rubber, for example.

In some embodiments, mixing is allowed 814 up to the extent that a specified thermal performance of the system is no longer achieved 836.

In some embodiments, the exhaust layer increases in volume to accommodate the increasing volume of air as more cooling layers provide heated flow into the exhaust layer. This helps reduce to prevent each successive input to the exhaust layer from restricting the incoming flow, causing turbulence, and/or cause backflow, for example.

In some embodiments, the total cross-sectional area of passage entries in a cooling chamber surface is the same as the cross-sectional area of the cooling chamber, to expedite air flow into the passages. Passage entry area may also be slightly larger than the cross-sectional area of the cooling chamber, since heated air tries to expand.

Some Additional Combinations and Variations

In one example, a method of managing airflow over a printed circuit board (PCB) 106 is provided. The PCB has electronic components 104 mounted in at least N groups on a component side 1100 of the PCB, N being at least 2. The method includes separating 802 an incoming stream of cooling air into at least M cooling layers 402 on the component side of the PCB, M being at least 2, and directing 804 cooling air from each cooling layer toward at least one respective group of electronic components and then to an exhaust region 1602, while permitting 814 at most an insignificant amount of mixing 844 between cooling layer air which has been directed toward electronic components and carried heat away from them, and cooling air which has not yet been directed toward electronic components. The amount of mixing is insignificant if it contributes a rise in each cooling layer air temperature of less than one-half of one degree Celsius, or if a flow rate of mixing air from a cooling layer is less than five percent of an overall flow rate from the cooling layer for each cooling layer.

In some cases, the directing directs cooling air from each cooling layer toward a single respective row of electronic components mounted on the PCB and then to an exhaust layer 404.

In some cases, the directing directs air from a cooling layer to the exhaust region through an enclosed passage 914 from the cooling layer.

In some cases, the separating produces a separation of the incoming stream of cooling air into layers without relying 816 on any moving parts to produce the separation.

In some cases, the PCB is mounted in a chassis 138, and the method avoids 840 bringing air which has been directed over electronic components mounted on the PCB and into the exhaust region back into thermal contact with the same or other electronic components mounted on the PCB until after the air has been exhausted from the chassis.

In some cases, air is exhausted from a chassis 138 from an exhaust layer 404 and is also exhausted directly from the chassis from exactly one of the cooling layers, namely, the cooling layer which has the longest path traveled by cooling air from a point at which the separating into layers occurs to a point at which air in the cooling layer carries heat away from electronic components.

In some cases, the method further includes sensing 822 and/or 826 at least one of the following items, and then modifying 842 air flow in response to the sensed item(s): a temperature 824 of air which has been directed over electronic components mounted on the PCB, a temperature 824 at a location on the PCB, a temperature 824 of a component which is mounted on the PCB, a rate of temperature 824 change, an air flow rate 828 over a location on the PCB, or an air flow rate 828 over a component which is mounted on the PCB.

In some cases, the method further includes achieving 836 at least a 9 degrees Celsius per Watt drop in thermal resistance 838 during powered operation of at least one electronic component mounted on the PCB when compared to powered operation of the same electronic component(s) without said separating and directing steps.

Some examples include a baffle 900. The baffle 900 may include at least one exhaust chamber surface 910 which defines an exhaust chamber 908, with the exhaust chamber surface having an exhaust outlet 912 and at least one passage exit 922. The baffle 900 may also include a plurality of cooling chamber surfaces 904 which define N cooling chambers 902, N being at least two, with at least one cooling chamber surface having an inlet 906, an electronics component threshold 920, and at least one passage entry 918. The baffle 900 may also include at least one passage surface 916, with each passage surface defining a passage 914 which connects to one of the cooling chambers at the passage's entry and connects to the exhaust chamber at the passage's exit.

In some cases, the baffle is in combination with and attached to a printed circuit board (PCB). The PCB 106 has electronic components 104 mounted on a component side 1100 of the PCB, with the electronic components positioned adjacent the electronics component thresholds of the baffle. In some of these cases, the cooling chamber surfaces 904 include a planar cooling chamber top surface, a planar cooling chamber bottom surface, and side walls connecting the top surface to the bottom surface, and the baffle is further characterized in at least one of the following ways: the cooling chamber top surface and the cooling chamber bottom surface are parallel to the PCB, e.g., as shown in FIG. 19 but not FIGS. 17 and 18; the cooling chamber top surface and the cooling chamber bottom surface are parallel to one another, e.g., as shown in FIGS. 17, 18, and 19; or the cooling chamber top surface and the cooling chamber bottom surface are each at an acute angle to the PCB, e.g., as shown in FIGS. 17 and 18 but not FIG. 19.

In some cases, the baffle is further characterized in that at least one electronics component threshold includes an opening 1800 through which cooling air can reach an electronics component when the baffle is attached to a printed circuit board on which the electronics component is mounted. In some cases, the baffle is further characterized in that at least one electronics component threshold includes a thermally conductive material 600 which cooling air can reach and then carry heat away from an electronics component when the baffle is attached to a printed circuit board on which the electronics component is mounted and the thermally conductive material of the electronics component threshold is placed against the electronics component.

In some cases, the cooling chambers 902 connect with one another inside the baffle only by way of the exhaust chamber 908 and one or more of the passages 914.

In some cases, the baffle 900 is further characterized in that the cooling chamber surfaces reside on a plurality of pieces which are stacked together, e.g., as indicated in FIG. 16, or all stacked pieces may reside on a single side of the PCB. In some, the baffle 900 is free of moving parts. In some, at least one passage is further characterized in that the cross-sectional area of the passage entry 918 is smaller than the cross-sectional area of the passage exit 922.

Any of these combinations of layers, surfaces, passages, openings and other thresholds, shapes, counts, configurations and/or their functional equivalents may also be combined with any of the baffles and their variations described above. A process of making or using a baffle may include any steps described herein in any subset or combination or sequence which is operable. Each variant may occur alone, or in combination with any one or more of the other variants. Each variant may occur with any of the processes and each process may be combined with any one or more of the other processes.

### CONCLUSION

Although particular embodiments of tools and techniques for airflow control patterns for cooling multiple in-line objects, for example, are expressly illustrated and described herein as processes, devices, or systems, it will be appreciated that discussion of one type of embodiment also generally extends to other embodiment types. For instance, the descriptions of processes in connection with FIG. 8 also help describe baffles, and help describe the technical effects and operation of systems and manufactures like those discussed in connection with other Figures. It does not follow that limitations from one embodiment are necessarily read into another. In particular, processes and baffles are not necessarily limited to the numbers, orderings, shapes and arrangements presented as examples.

Reference herein to an embodiment having some feature X and reference elsewhere herein to an embodiment having some feature Y does not exclude from this disclosure embodiments which have both feature X and feature Y, unless such exclusion is expressly stated herein. All possible negative claim limitations are within the scope of this disclosure, in the sense that any feature which is stated to be part of an embodiment may also be expressly removed from inclusion in another embodiment, even if that specific exclusion is not given in any example herein. The term “embodiment” is merely used herein as a more convenient form of “process, system, article of manufacture, and/or other example of the teachings herein as applied in a manner consistent with applicable law.” Accordingly, a given “embodiment” may include any combination of features disclosed herein, provided the embodiment is consistent with at least one claim.

Not every item shown in the Figures need be present in every embodiment. Conversely, an embodiment may contain item(s) not shown expressly in the Figures. Although some possibilities are illustrated here in text and drawings by specific examples, embodiments may depart from these examples. For instance, specific technical effects or technical features of an example may be omitted, renamed, grouped differently, repeated, instantiated in hardware and/or software differently, or be a mix of effects or features appearing in two or more of the examples. Functionality shown at one location may also be provided at a different location in some embodiments; one of skill recognizes that functionality modules can be defined in various ways in a given implementation without necessarily omitting desired technical effects from the collection of interacting modules viewed as a whole.

Reference has been made to the figures throughout by reference numerals. Any apparent inconsistencies in the phrasing associated with a given reference numeral, in the figures or in the text, should be understood as simply broadening the scope of what is referenced by that numeral. Different instances of a given reference numeral may refer to different embodiments, even though the same reference numeral is used.

As used herein, terms such as “a” and “the” are inclusive of one or more of the indicated item or step. In particular, in the claims a reference to an item generally means at least one such item is present and a reference to a step means at least one instance of the step is performed.

Headings are for convenience only; information on a given topic may be found outside the section whose heading indicates that topic.

All claims and the abstract, as filed, are part of the specification.

While exemplary embodiments have been shown in the drawings and described above, it will be apparent to those of ordinary skill in the art that numerous modifications can be made without departing from the principles and concepts set forth in the claims, and that such modifications need not encompass an entire abstract concept. Although the subject matter is described in language specific to structural features and/or procedural acts, it is to be understood that the subject matter defined in the appended claims is not necessarily limited to the specific technical features or acts described above the claims. It is not necessary for every means or aspect or technical effect identified in a given definition or example to be present or to be utilized in every embodiment. Rather, the specific features and acts and effects described are disclosed as examples for consideration when implementing the claims.

All changes which fall short of enveloping an entire abstract idea but come within the meaning and range of equivalency of the claims are to be embraced within their scope to the full extent permitted by law.

What is claimed is:

1. A method of managing airflow over a printed circuit board (PCB), the PCB having electronic components mounted in at least N groups on a component side of the PCB, N being at least 2, the method comprising:
separating an incoming stream of cooling air into at least M cooling layers on the component side of the PCB, M being at least 2; and
directing cooling air from each cooling layer toward at least one respective group of electronic components and then to an exhaust region, while permitting at most an insignificant amount of mixing between cooling layer air which has been directed toward electronic components and carried heat away from them, and cooling air which has not yet been directed toward electronic components, where the amount of mixing is insignificant if it contributes a rise in each cooling layer air temperature of less than one-half of one degree Celsius.

2. The method of claim 1, wherein the directing directs cooling air from each cooling layer toward a single respective row of electronic components mounted on the PCB and then to an exhaust layer.

3. The method of claim 1, wherein the directing directs air from a cooling layer to the exhaust region through an enclosed passage from the cooling layer.

4. The method of claim 1, wherein the separating produces a separation of the incoming stream of cooling air into layers without relying on any moving parts to produce the separation.

5. The method of claim 1, wherein the PCB is mounted in a chassis, and the method avoids bringing air which has been directed over electronic components mounted on the PCB and into the exhaust region back into thermal contact with the same or other electronic components mounted on the PCB until after the air has been exhausted from the chassis.

6. The method of claim 1, wherein air is exhausted from a chassis from an exhaust layer and is also exhausted directly from the chassis from exactly one of the cooling layers, namely, the cooling layer which has the longest path traveled by cooling air from a point at which the separating into layers occurs to a point at which air in the cooling layer carries heat away from electronic components.

7. The method of claim 1, further comprising sensing at least one of the following items, and then modifying air flow in response to the sensed item(s):
a temperature of air which has been directed over electronic components mounted on the PCB;
a temperature at a location on the PCB;
a temperature of a component which is mounted on the PCB;
a rate of temperature change;
an air flow rate over a location on the PCB; or
an air flow rate over a component which is mounted on the PCB.

8. A baffle comprising:
at least one exhaust chamber surface which defines an exhaust chamber, the exhaust chamber surface having an exhaust outlet and at least one passage exit;
a plurality of cooling chamber surfaces which define N cooling chambers, N being at least two, at least one cooling chamber surface having an inlet, an electronics component threshold, and at least one passage entry; and
at least one passage surface, each passage surface defining a passage which connects to one of the cooling chambers at the passage's entry and connects to the exhaust chamber at the passage's exit.

9. The baffle of claim 8, in combination with and attached to a printed circuit board (PCB), the PCB having electronic components mounted on a component side of the PCB, the electronic components positioned adjacent the electronics component thresholds of the baffle.

10. The baffle of claim 9, wherein the cooling chamber surfaces include a planar cooling chamber top surface, a planar cooling chamber bottom surface, and side walls connecting the top surface to the bottom surface.

11. The baffle of claim 10, wherein the baffle is further characterized in at least one of the following ways:
the cooling chamber top surface and the cooling chamber bottom surface are parallel to the PCB;
the cooling chamber top surface and the cooling chamber bottom surface are parallel to one another; or
the cooling chamber top surface and the cooling chamber bottom surface are each at an acute angle to the PCB.

12. The baffle of claim 8, wherein the baffle is further characterized in at least one of the following ways:
at least one electronics component threshold includes an opening through which cooling air can reach an electronics component when the baffle is attached to a printed circuit board on which the electronics component is mounted; or
at least one electronics component threshold includes a thermally conductive material which cooling air can reach and then carry heat away from an electronics component when the baffle is attached to a printed circuit board on which the electronics component is mounted and the thermally conductive material of the electronics component threshold is placed against the electronics component.

13. The baffle of claim 8, wherein the cross-sectional area of a cooling chamber orthogonal to airflow direction is within a range from 90% to 110% of the total cross-sectional area of passage entries leaving that cooling chamber.

14. The baffle of claim 8, wherein the cooling chambers connect with one another inside the baffle only by way of the exhaust chamber and one or more of the passages.

15. The baffle of claim 8, wherein the baffle is further characterized in at least one of the following ways:
the cooling chamber surfaces reside on a plurality of pieces which are stacked together; or
the baffle is free of moving parts.

16. The baffle of claim 8, wherein at least one passage is further characterized in that the cross-sectional area of the passage entry is smaller than the cross-sectional area of the passage exit.

17. A method of managing airflow over a printed circuit board (PCB), the method comprising:
separating an incoming stream of cooling air into at least two layers of cooling air on a component side of the PCB; and
directing cooling air from each layer over a respective set of one or more electronic components mounted on the PCB and then through at least one enclosed passage to an exhaust region, thereby cooling the electronic components while inhibiting mixing between air which has been directed over electronic components and air which has not, wherein the inhibiting mixing occurs when at least one of the following conditions is satisfied: mixing contributes a rise in cooling layer air temperature of at most one degree Celsius for each cooling layer, or a flow rate of mixing air from a cooling layer is less than five percent of an overall flow rate from the cooling layer for each cooling layer.

18. The method of claim 17, comprising at least one of the following:
directing cooling air over at least 90% of the total exposed surface area of the electronic components mounted on the PCB;
directing cooling air over at least 60% of the sum of (a) total exposed surface area of the electronic components mounted on the PCB, and (b) total exposed surface area of a side of the PCB on which the electronic components are mounted; or
achieving at least a 6 degrees Celsius per Watt drop in thermal resistance during powered operation of at least one electronic component mounted on the PCB when compared to powered operation of the same electronic component(s) without said separating and directing steps.

19. The method of claim 17, wherein the exhaust region includes an exhaust layer into which at least one enclosed passage exhausts heated air and the exhaust region also includes a layer direct exit region at a layer's end.

20. The method of claim 17, comprising achieving at least a 9 degrees Celsius per Watt drop in thermal resistance during powered operation of at least one electronic component mounted on the PCB when compared to powered operation of the same electronic component(s) without said separating and directing steps.
